(19) United States
(12) Patent Application Publication
(10) Pub. No.: US 2025/0194164 A1
(43) Pub. Date: Jun. 12, 2025

(54) LOCAL INTERCONNECT IN SEQUENTIAL STACKING

(71) Applicant: International Business Machines Corporation, Armonk, NY (US)

(72) Inventors: Chen Zhang, Santa Clara, CA (US); Shay Reboh, Guilderland, NY (US); James P. Mazza, Saratoga Springs, NY (US); Ruilong Xie, Niskayuna, NY (US); Tenko Yamashita, Schenectady, NY (US)

(21) Appl. No.: 18/536,400

(22) Filed: Dec. 12, 2023

(51) Int. Cl. H01L 29/786; H01L 21/8238; H01L 23/522; H01L 27/088; H01L 29/06; H01L 29/423; H01L 29/66; H01L 29/775

(52) U.S. Cl. CPC H10D 30/6757; H01L 23/5226; H10D 30/014; H10D 30/43; H10D 30/6735; H10D 62/121; H10D 64/017; H10D 84/017; H10D 84/0186; H10D 84/038; H10D 84/83

(57) ABSTRACT

Embodiments of the present disclosure relate to a local interconnect in sequential stacking of transistors. A semiconductor structure includes a first transistor stacked under a second transistor. An interconnect layer is between the first and second transistors, the interconnect layer including a conductive via and a conductive line.

### BACKGROUND

The present disclosure generally relates to fabrication methods and resulting structures for integrated circuits (ICs), and more specifically, to fabrication methods and resulting structures having a local interconnect in sequential stacking of transistors.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present disclosure are directed to providing a local interconnect in sequentially stacked transistors. A non-limiting method of forming a semiconductor structure includes providing a first transistor. The method includes forming an interconnect layer between the first transistor and a second transistor, the first transistor being under the second transistor, the interconnect layer comprising a conductive via and a conductive line.

According to one or more embodiments, a non-limiting method of forming a semiconductor structure includes providing a first transistor having a first gate. The method includes providing a second transistor having a second gate, the second transistor being stacked above the first transistor, where an interconnect layer is formed between the first and second transistors, the interconnect layer electrically connecting the first gate and the second gate.

Other embodiments of the present disclosure implement features of the above-described devices/structures in methods and/or implement features of the methods in devices/structures.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIGS. 1A, 1B, 1C, and 1D respectively depict a top view and cross-sectional views of a portion of an integrated circuit (IC) under-fabrication according to one or more embodiments;

FIGS. 2A, 2B, 2C, and 2D respectively depict a top view and cross-sectional views of a portion of an IC under-fabrication after fabrication operations according to one or more embodiments;

FIGS. 3A, 3B, 3C, and 3D respectively depict a top view and cross-sectional views of a portion of an IC under-fabrication after fabrication operations according to one or more embodiments;

FIGS. 4A, 4B, 4C. and 4D respectively depict a top view and cross-sectional views of a portion of an IC under-fabrication after fabrication operations according to one or more embodiments;

FIGS. 5A, 5B, 5C, and 5D respectively depict a top view and cross-sectional views of a portion of an IC under-fabrication after fabrication operations according to one or more embodiments;

FIGS. 6A, 6B, 6C, and 6D respectively depict a top view and cross-sectional views of a portion of an IC under-fabrication after fabrication operations according to one or more embodiments;

FIGS. 7A, 7B, 7C, and 7D respectively depict a top view and cross-sectional views of a portion of an IC under-fabrication after fabrication operations according to one or more embodiments;

FIGS. 8A, 8B, 8C, and 8D respectively depict a top view and cross-sectional views of a portion of an IC under-fabrication after fabrication operations according to one or more embodiments;

FIGS. 9A, 9B, 9C, and 9D respectively depict a top view and cross-sectional views of a portion of an IC under-fabrication after fabrication operations according to one or more embodiments;

FIGS. 10A, 10B, 10C, and 10D respectively depict a top view and cross-sectional views of a portion of an IC under-fabrication after fabrication operations according to one or more embodiments;

FIGS. 11A, 11B, 11C, and 11D respectively depict a top view and cross-sectional views of a portion of an IC under-fabrication after fabrication operations according to one or more embodiments;

FIGS. 12A, 12B, 12C, and 12D respectively depict a top view and cross-sectional views of a portion of an IC under-fabrication after fabrication operations according to one or more embodiments;

FIGS. 13A, 13B, 13C, and 13D respectively depict a top view and cross-sectional views of a portion of an IC under-fabrication after fabrication operations according to one or more embodiments;

FIG. 14 depicts a flowchart of a method of forming a semiconductor structure according to one or more embodiments; and

FIG. 15 depicts a flowchart of a method of forming a semiconductor structure according to one or more embodiments.

### DETAILED DESCRIPTION

One or more embodiments of the present disclosure relate to providing a local interconnect in sequential stacking of transistors. A semiconductor structure includes a first transistor stacked under a second transistor and an interconnect layer between the first and second transistors, the interconnect layer including a conductive via and a conductive line.

This provides an improved electrical connection for sequentially stacked transistors especially given the increases in transistor density on semiconductor structures. Sequential stacking is very attractive because it avoids the high aspect ratio process in monolithic stacking. However, it may incur problems regarding an impact of the top transistor process on the performance and reliability of the bottom transistor. This disclosure provides the unique improvement of inserting additional interconnect layers in between the top transistor and the bottom transistor for sequential stacking, which is difficult to achieve in monolithic stacking. The conductive via and conductive line between the top transistor and the bottom transistor are used to form a small footprint logic cross-couple structure that helps significantly with area scaling.

In addition to one or more of the features described above or below, additional features include where the interconnect layer electrically connects the first transistor to the second transistor. This advantageously provides cross coupling for stacked transistors.

In addition to one or more of the features described above or below, additional features include where the interconnect layer electrically connects a first gate of the first transistor to a second gate of the second transistor. This advantageously provides an interconnect layer for cross coupling gates of stacked transistors.

In addition to one or more of the features described above or below, additional features include where the conductive via connects the first transistor to the conductive line. This advantageously provides cross coupling for stacked transistors.

In addition to one or more of the features described above or below, additional features include where another conductive via connects the second transistor to the conductive line. This advantageously provides cross coupling for stacked transistors.

In addition to one or more of the features described above or below, additional features include where a space between the first transistor and the second transistor includes the conductive via, the conductive line, and the another conductive via. This advantageously provides cross coupling for stacked transistors.

In addition to one or more of the features described above or below, additional features include where a first gate of the first transistor is connected to a conductive connection, another conductive via being connected to both the conductive connection and the conductive line, the conductive line being connected to the conductive via; a second gate of the second transistor is connected to the conductive via. This advantageously provides an interconnect structure for cross coupling stacked transistors.

In addition to one or more of the features described above or below, additional features include where gates of the first and second transistors are connected by the interconnect layer for simultaneous control. This advantageously allows stacked transistors to be simultaneously driven.

In addition to one or more of the features described above or below, additional features include where a first gate of the first transistor is directly under a second gate of the second transistor; or the first gate of the first transistor is diagonally offset under the second gate of the second transistor. This advantageously allows stacked transistors to be simultaneously driven.

In addition to one or more of the features described above or below, additional features include where: a top tier includes the second transistor and a fourth transistor, the fourth transistor being laterally adjacent to the second transistor; a bottom tier includes the first transistor and a third transistor, the first transistor being directly below the second transistor, the third transistor being directly below the fourth transistor; and gates of the first and fourth transistors are connected and other gates of the second and third transistors are connected. This advantageously allows adjacent sets of stacked transistors to be cross connected.

According to one or more embodiments, a method for a semiconductor structure is provided. A method includes providing a first transistor, and forming an interconnect layer between the first transistor and a second transistor, the first transistor being under the second transistor, the interconnect layer comprising a conductive via and a conductive line.

This provides an improved electrical connection for sequentially stacked transistors especially given the increases in transistor density on semiconductor structures. Sequential stacking is very attractive because it avoids the high aspect ratio process in monolithic stacking, but it may incur problems regarding an impact of the top transistor process on the performance and reliability of the bottom transistor. This disclosure provides the unique improvement of inserting additional interconnect layers in between the top transistor and the bottom transistor for sequential stacking, which is difficult to achieve in monolithic stacking. The conductive via and conductive line between the top transistor and the bottom transistor are used to form a small footprint logic cross-couple structure that helps significantly with area scaling.

In addition to one or more of the features described above or below, additional features include where the interconnect layer electrically connects the first transistor to the second transistor. This advantageously provides cross coupling for stacked transistors.

In addition to one or more of the features described above or below, additional features include where the interconnect layer electrically connects a first gate of the first transistor to a second gate of the second transistor. This advantageously provides an interconnect layer for cross coupling gates of stacked transistors.

In addition to one or more of the features described above or below, additional features include where the conductive via connects the first transistor to the conductive line. This advantageously provides cross coupling for stacked transistors.

In addition to one or more of the features described above or below, additional features include where another conductive via connects the second transistor to the conductive line. This advantageously provides cross coupling for stacked transistors.

In addition to one or more of the features described above or below, additional features include where a space between the first transistor and the second transistor includes the conductive via, the conductive line, and the another conductive via. This advantageously provides cross coupling for stacked transistors.

In addition to one or more of the features described above or below, additional features include where a first gate of the first transistor is connected to a conductive connection, another conductive via being connected to both the conductive connection and the conductive line, the conductive line being connected to the conductive via; a second gate of the second transistor is connected to the conductive via. This advantageously provides an interconnect structure for cross coupling stacked transistors.

In addition to one or more of the features described above or below, additional features include where gates of the first and second transistors are connected by the interconnect layer for simultaneous control. This advantageously allows stacked transistors to be simultaneously driven.

According to one or more embodiments, a semiconductor structure is provided. The semiconductor structure includes a first transistor having a first gate, and a second transistor having a second gate, the second transistor being stacked above the first transistor. The semiconductor structure includes an interconnect layer formed between the first and second transistors, the interconnect layer electrically connecting the first gate and the second gate.

This provides an improved electrical connection for sequentially stacked transistors especially given the increases in transistor density on semiconductor structures. Sequential stacking is very attractive because it avoids the high aspect ratio process in monolithic stacking. However, it may incur problems regarding an impact of the top transistor process on the performance and reliability of the bottom transistor. This disclosure provides the unique improvement of inserting additional interconnect layers in between the top transistor and the bottom transistor for sequential stacking, which is difficult to achieve in monolithic stacking. The conductive via and conductive line between the top transistor and the bottom transistor are used to form a small footprint logic cross-couple structure that helps significantly with area scaling.

In addition to one or more of the features described above or below, additional features include where the interconnect layer includes a first conductive via, a conductive line, and a second conductive via. This advantageously provides an interconnect layer for cross coupling gates of stacked transistors.

In addition to one or more of the features described above or below, additional features include where the interconnect layer includes a first conductive via that connects to the first gate, a second conductive via that connects to the second gate, and a conductive line connected to both the first and second conductive vias. This advantageously provides an interconnect layer for cross coupling gates of stacked transistors.

In addition to one or more of the features described above or below, additional features include where a conductive connection connects the first gate to a first conductive via; and the interconnect layer includes the first conductive via connected to the conductive connection, a second conductive via connected to the second gate, and a conductive line connected to both the first and second conductive vias. This advantageously provides cross coupling for stacked transistors.

In addition to one or more of the features described above or below, additional features include where the first and second gates are connected by the interconnect layer for simultaneous control. This advantageously allows stacked transistors to be simultaneously driven.

According to one or more embodiments, a method for a semiconductor structure is provided. The method includes providing a first transistor having a first gate, and providing a second transistor having a second gate, the second transistor being stacked above the first transistor, where an interconnect layer is formed between the first and second transistors, the interconnect layer electrically connecting the first gate and the second gate.

This provides an improved electrical connection for sequentially stacked transistors especially given the increases in transistor density on semiconductor structures. Sequential stacking is very attractive because it avoids the high aspect ratio process in monolithic stacking. However, it may incur problems regarding an impact of the top transistor process on the performance and reliability of the bottom transistor. This disclosure provides the unique improvement of inserting additional interconnect layers in between the top transistor and the bottom transistor for sequential stacking, which is difficult to achieve in monolithic stacking. The conductive via and conductive line between the top transistor and the bottom transistor are used to form a small footprint logic cross-couple structure that helps significantly with area scaling.

In addition to one or more of the features described above or below, additional features include where the interconnect layer includes a first conductive via, a conductive line, and a second conductive via. This advantageously provides an interconnect layer for cross coupling gates of stacked transistors.

In addition to one or more of the features described above or below, additional features include where the interconnect layer includes a first conductive via that connects to the first gate, a second conductive via that connects to the second gate, and a conductive line connected to both the first and second conductive vias. This advantageously provides an interconnect layer for cross coupling gates of stacked transistors.

In addition to one or more of the features described above or below, additional features include where a conductive connection connects the first gate to a first conductive via; and the interconnect layer includes the first conductive via connected to the conductive connection, a second conductive via connected to the second gate, and a conductive line connected to both the first and second conductive vias. This advantageously provides cross coupling for stacked transistors.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

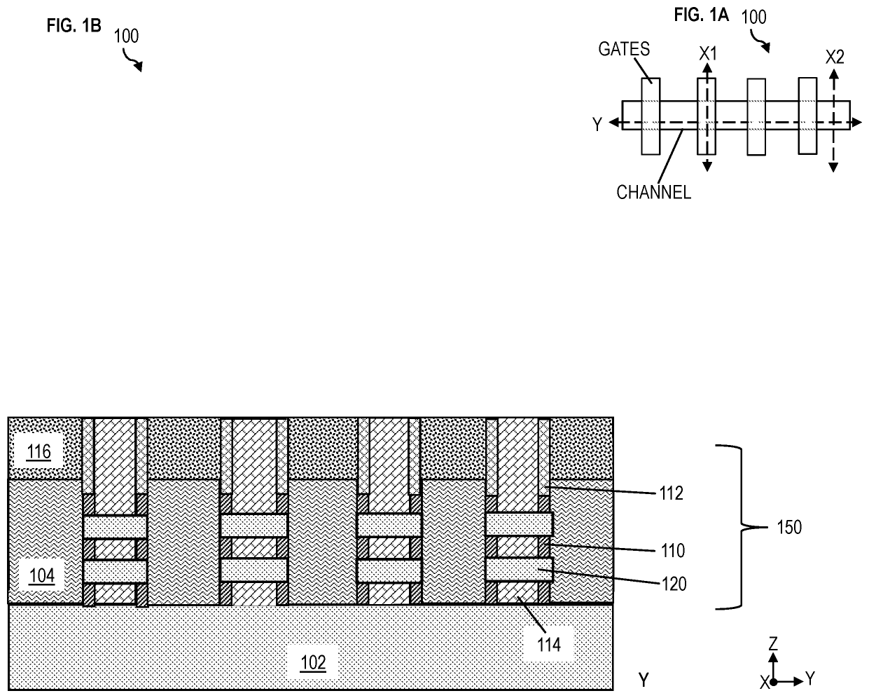

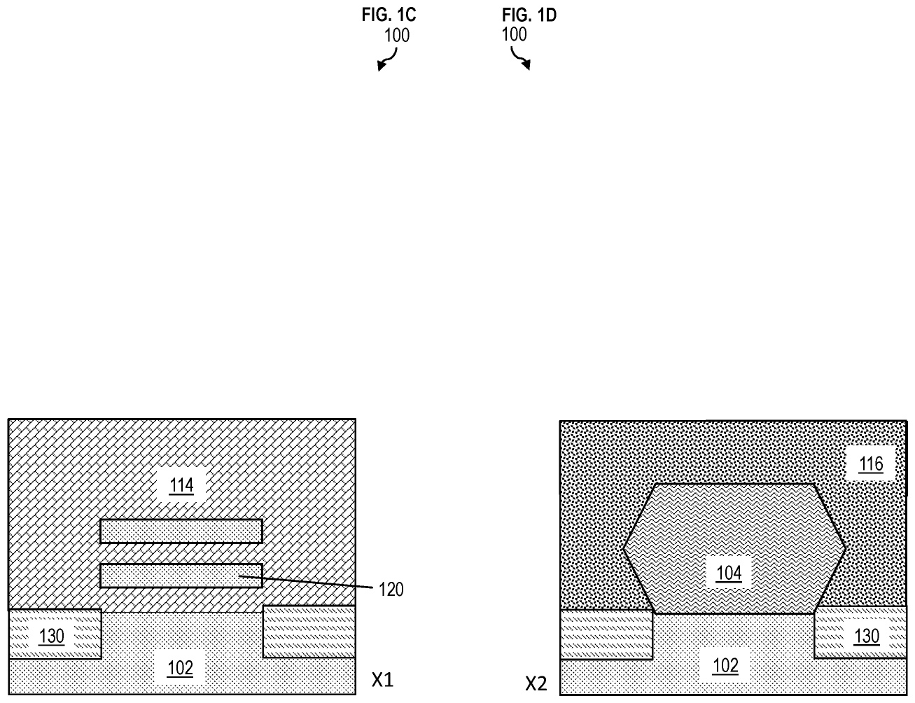

Turning now to a more detailed description of aspects of the present disclosure, FIG. 1A depicts a top view of a simplified illustration of a portion of an integrated circuit (IC) 100, FIG. 1B depicts a cross-sectional view taken along Y of the IC 100, FIG. 1C depicts a cross-sectional view taken along X1 of the IC 100, and FIG. 1D depicts a cross-sectional view taken along X2 of the IC 100. An additional cross-sectional view may be depicted along X3 in subsequent figures. For ease of understanding, some layers may be omitted from the various top views so as not to obscure the figure and to view layers underneath. As such, the top view is intended to provide a simplified illustration and a general orientation of a portion of the IC. Standard semiconductor fabrication techniques can be utilized to fabricate the IC as understood by one of ordinary skill in the art. Any suitable lithography processes including deposition techniques and etching techniques can be utilized herein.

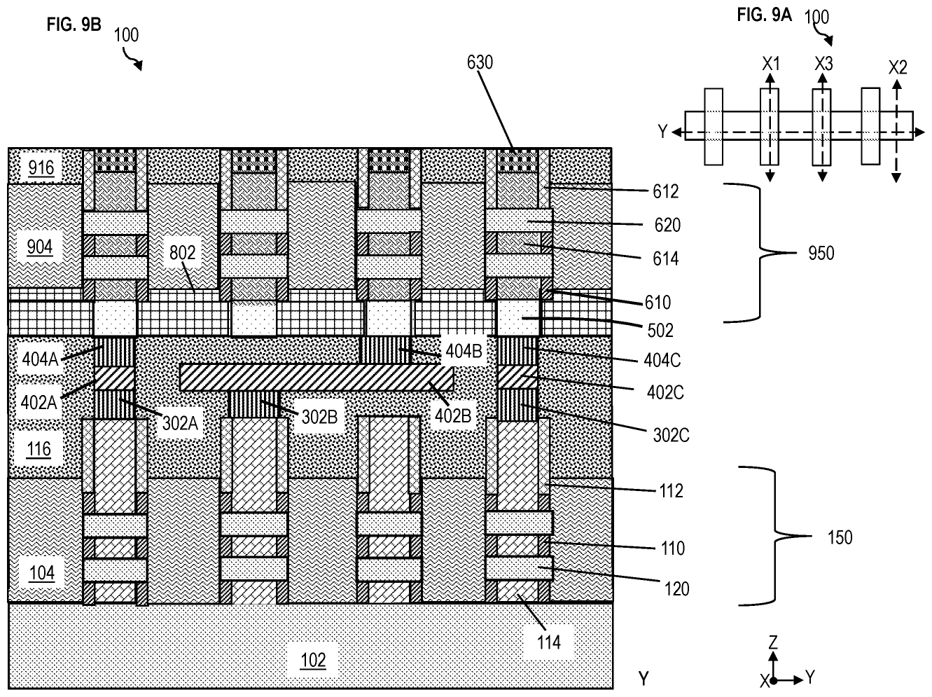

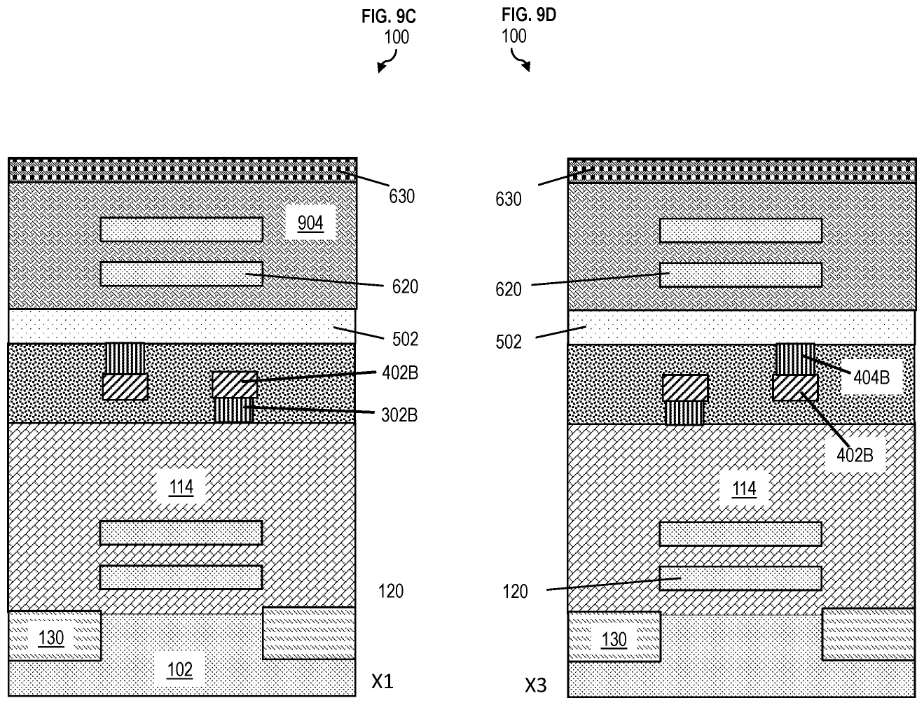

FIGS. 1A, 1B, 1C, and 1D depict the IC 100 after several fabrication operations. Top transistors 950 (depicted in FIG. 9B) are sequentially stacked on bottom transistors 150. The bottom transistors 150 are formed on a substrate 102. The substrate 102 (or wafer) may be formed of (pure) silicon. Other suitable materials can be utilized for the substrate 102. The bottom transistors 150 include bottom gate material 114 wrapped around bottom channel regions 120. The bottom channel regions 120 can be nanosheets and are separated by bottom inner spacers 110. Bottom source/drain regions 104 are formed on opposite sides of the bottom channel regions 120 and can be doped with p-type dopants or n-type dopants according to the type of transistor. Bottom gate spacers 112 are formed on the bottom gate material 114, and interlayer dielectric (ILD) layer 116 is formed on the bottom source/drain regions 104. Shallow trench isolation (STI) regions 130 are formed in the substrate 102.

The bottom gate material 114 can include a gate stack formed of a high-k dielectric material formed on the channel regions and a workfunction material formed on the high-k dielectric material. The workfunction material includes a work function suitable for enhancing the electrical properties of n-type or p-type semiconductor devices depending on the type of transistor being formed. Example materials of the bottom inner spacers 110 and the bottom gate spacers 112 can include silicon nitride (SiN), porous silicon carbon nitride (SiCN), carbon-doped oxide dielectric material including silicon, carbon, oxygen, and hydrogen (SiCOH), and octamethylcyclotetrasiloxane (OMCTS). Example materials of the STI regions 130 can include silicon dioxide. The ILD material of the ILD layer 116 can include low-k dielectric materials, ultra-low-k dielectric materials, etc.

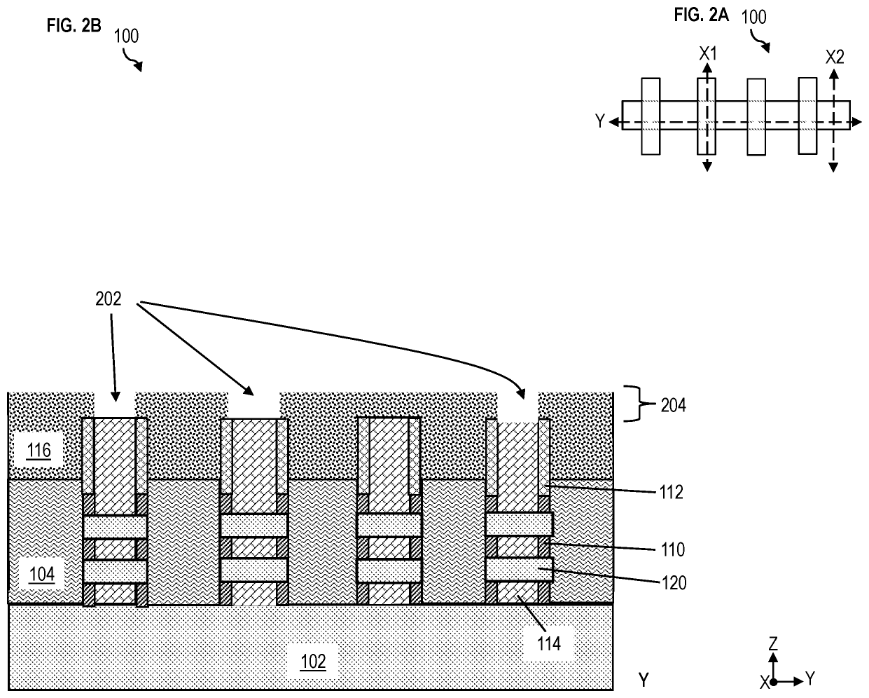

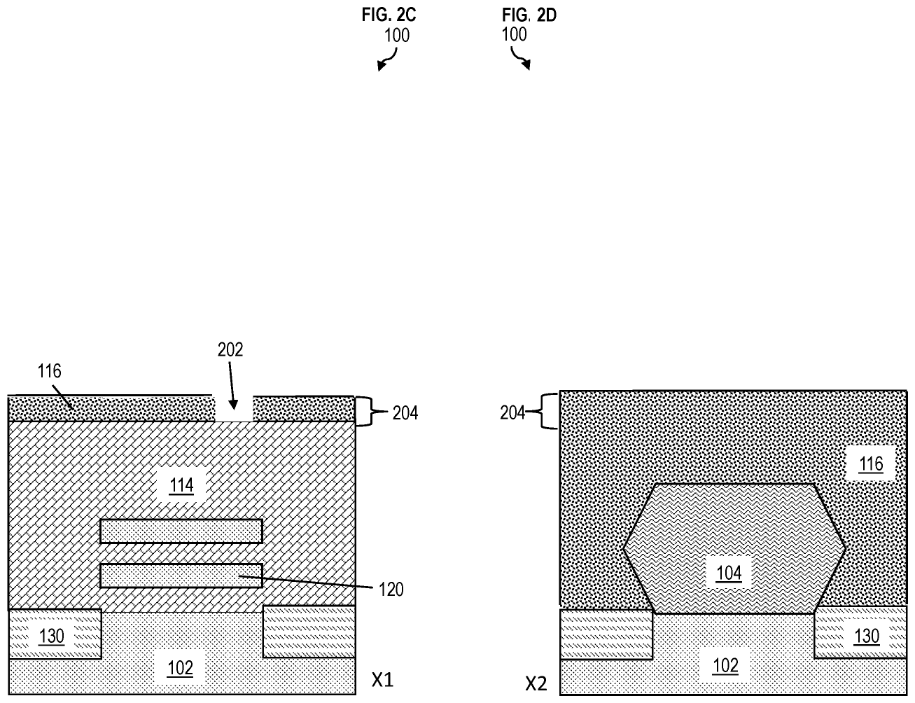

FIGS. 2A, 2B, 2C, and 2D depict the IC 100 in the process of forming an interconnect layer. Additional ILD material 204 is deposited to expand the ILD layer 116, and lithography is performed to pattern cavities 202 that expose the bottom gate material 114 in preparation for metal vias.

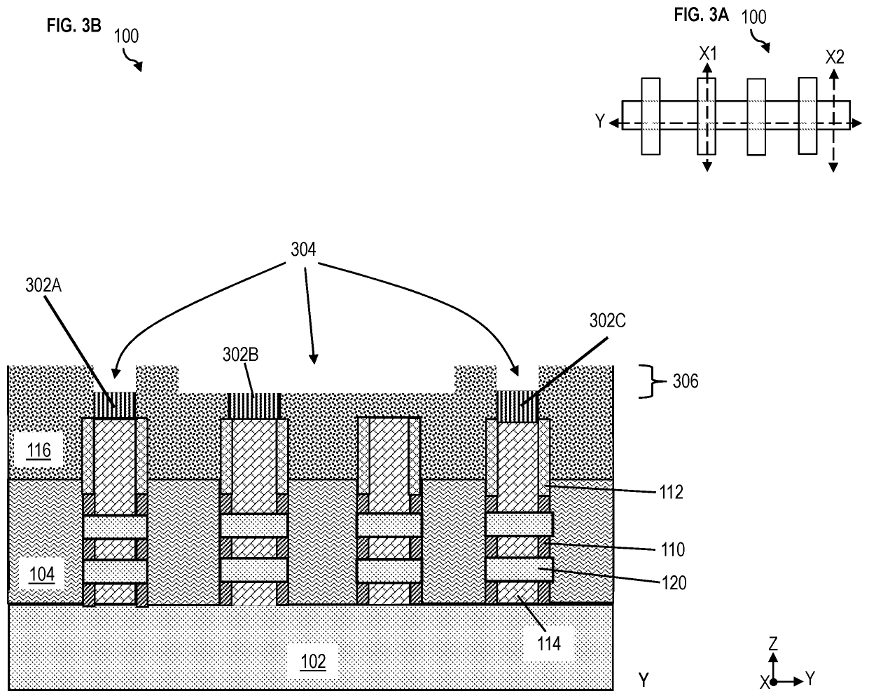

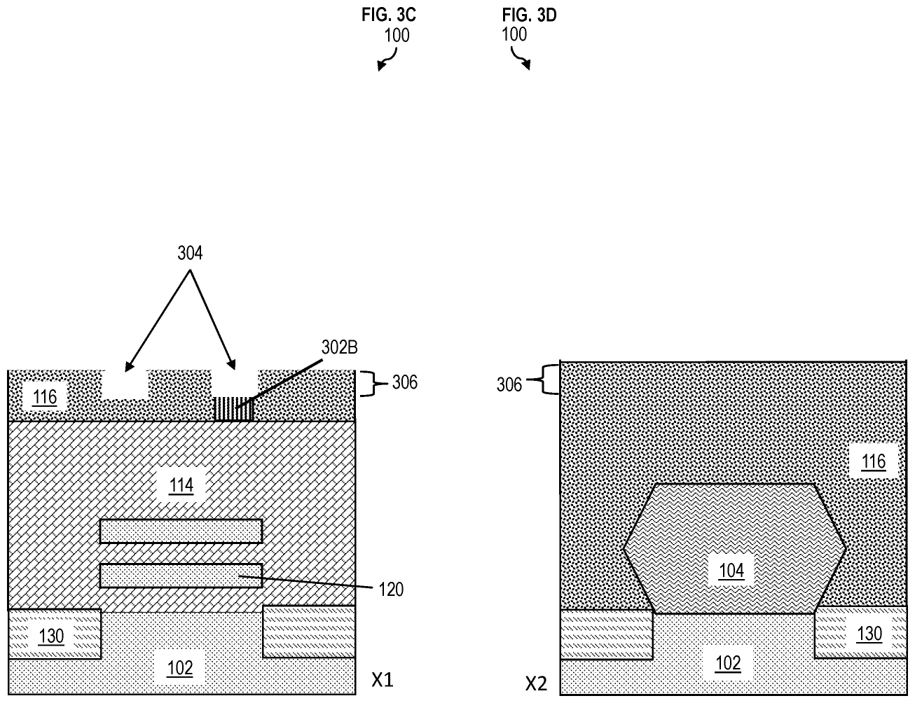

FIGS. 3A, 3B, 3C, and 3D depict the IC 100 after metallization of the vias. Metal is deposited to form metal vias 302A, 302B, and 302C and other metal vias (not shown). The metal vias 302A, 302B, and 302C can generally be referred to as metal vias 302. Additional ILD material 306 is deposited to expand the ILD layer 116 thereby forming another interconnect layer, and lithography is performed to pattern trenches 304 in the ILD layer 116 in preparation for metal wires/lines.

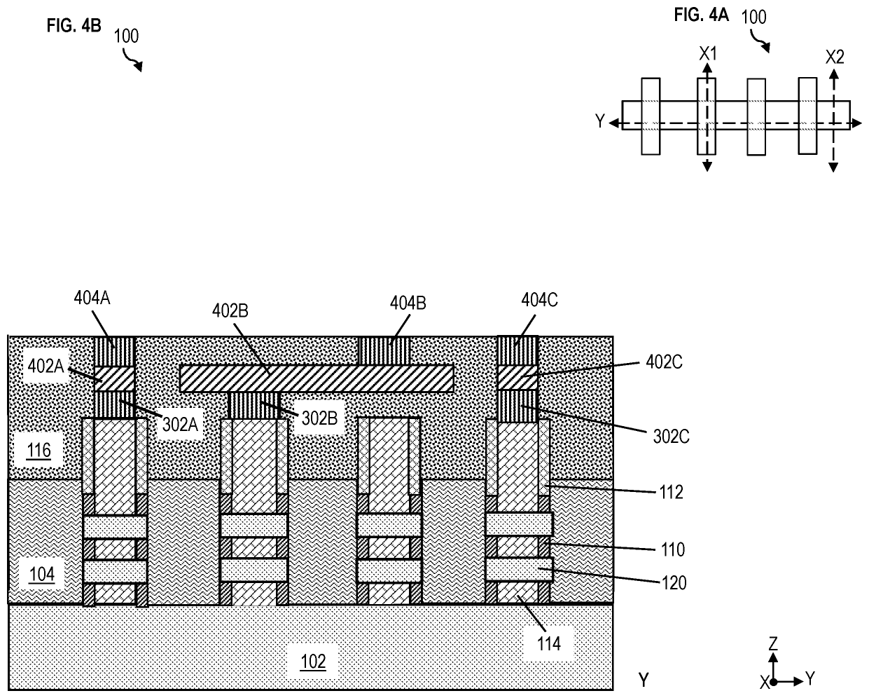

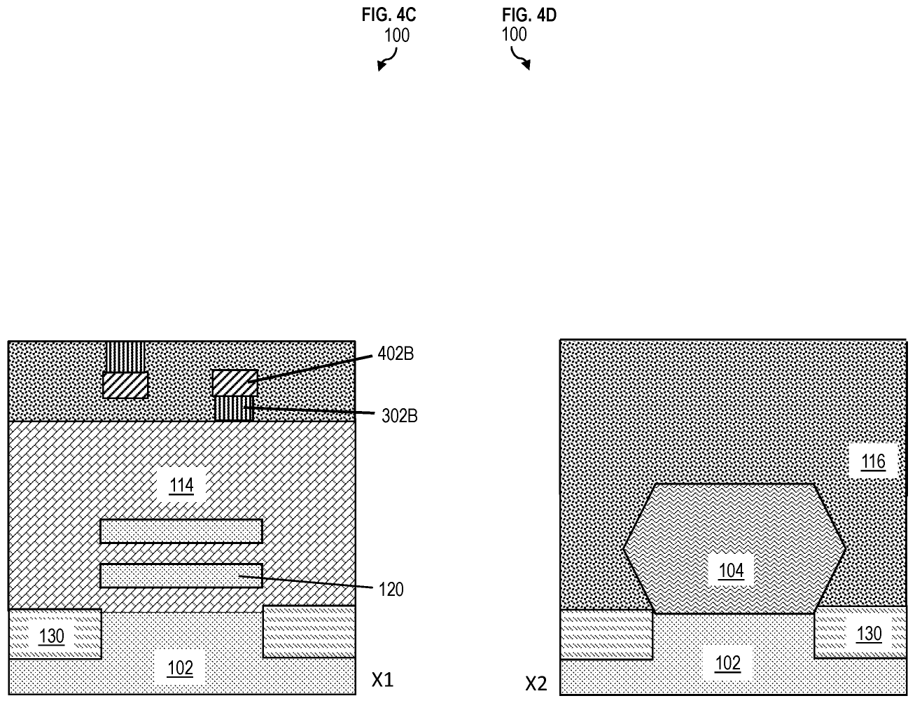

FIGS. 4A, 4B, 4C, and 4D depict the IC 100 after metallization of the metal wires/lines, patterning of upper vias, and metallization of the upper vias. Metal is deposited to form metal wires/lines 402A, 402B, and 402C and other metal wires/lines (not shown). The metal wires/lines 402A, 402B, and 402C can generally be referred to as metal wires/lines 402. Some metal wires/lines 402 may extend longitudinally in the y-axis and some may extend longitudinally in the x-axis.

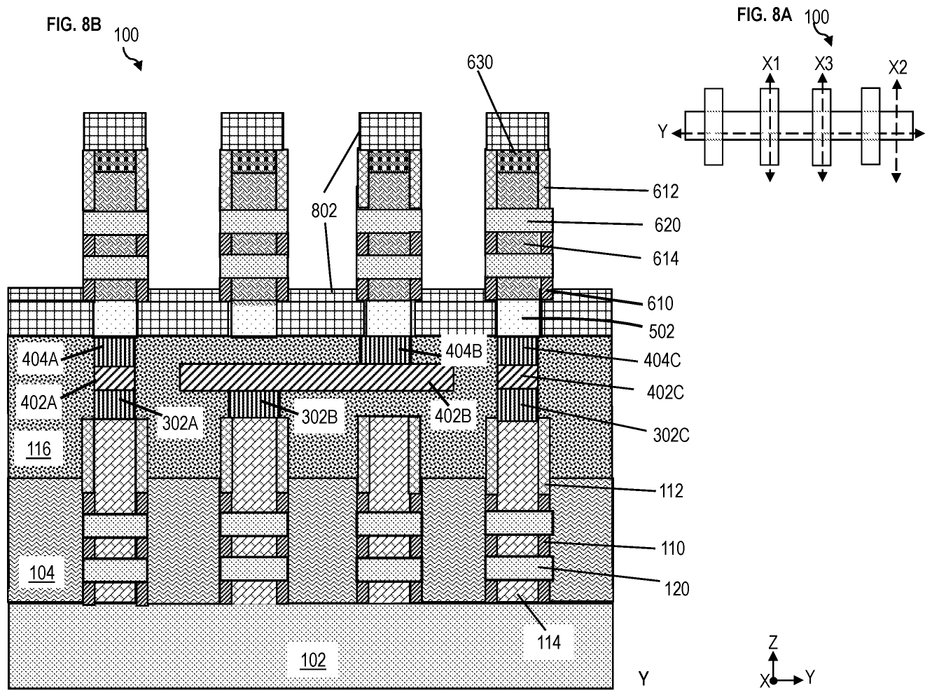

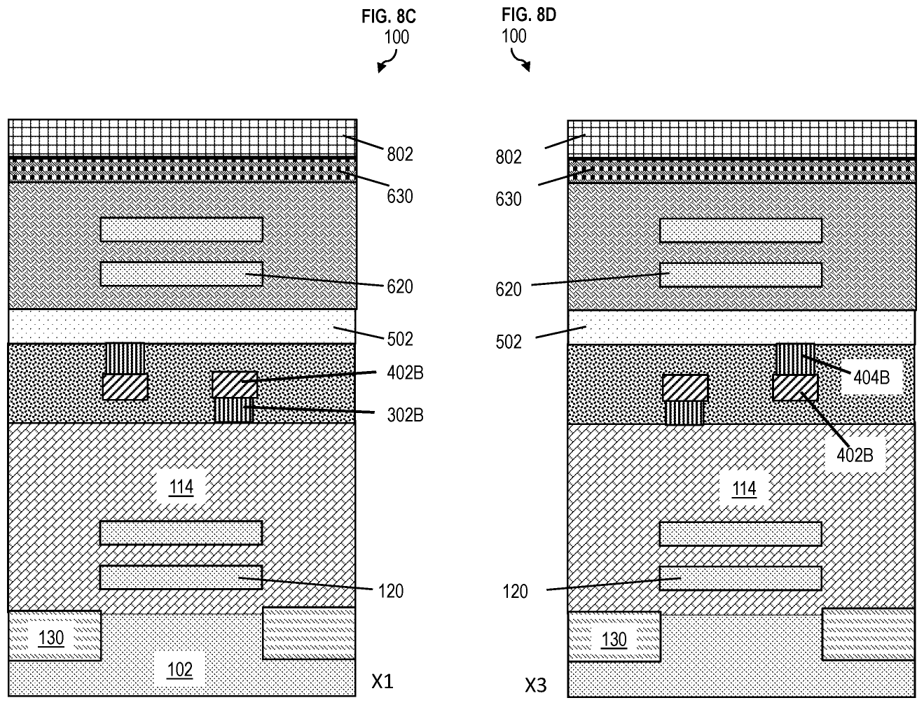

Additional ILD material is deposited to expand the ILD layer 116 thereby forming another interconnect layer, and lithography is performed to pattern cavities in the ILD layer 116. Then, metal is deposited to form metal vias 404A, 404B, and 404C and other metal vias (not shown). The metal vias 404A, 404B, and 404C can generally be referred to as metal vias 404, which are above the metal vias 302. As seen in FIG. 4B, the metal via 302B, the metal wire/line 402B, and the metal via 404B form a cross connection or cross couple between a bottom transistor and a top transistor (e.g., depicted in FIGS. 8B and 9B). The metal via 302B, the metal wire/line 402B, and the metal via 404B are physically and electrically connected.

It is noted that the metal vias 302A, 302B, and 302C are formed in the V1 layer, the metal wires/lines 402A, 402B, and 402C are formed in the M1 layer, and the metal vias 404A, 404B, and 404C are formed in the V2 layer. The metal vias 302, the metal wires/lines 402, and the metal vias 404 can include conductive materials. Example conductive materials can include ruthenium (Ru), tungsten (W), titanium (Ti), molybdenum (Mo), gold (Au), copper (Cu), nickel (Ni), aluminum (Al), etc. In one or more embodiments, a liner can be deposited such as a liner of Ti/TiN prior to the conductive material.

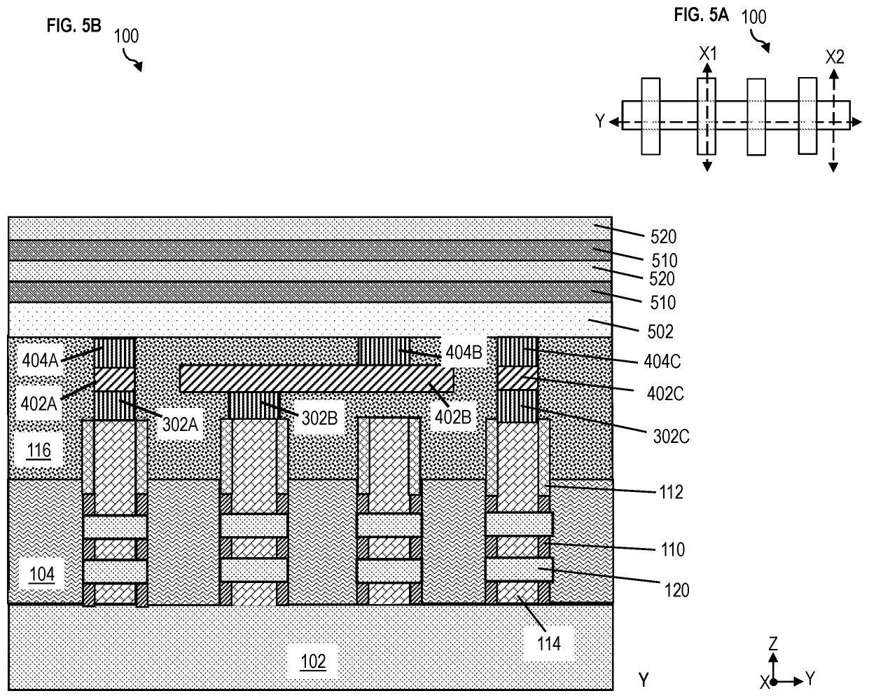

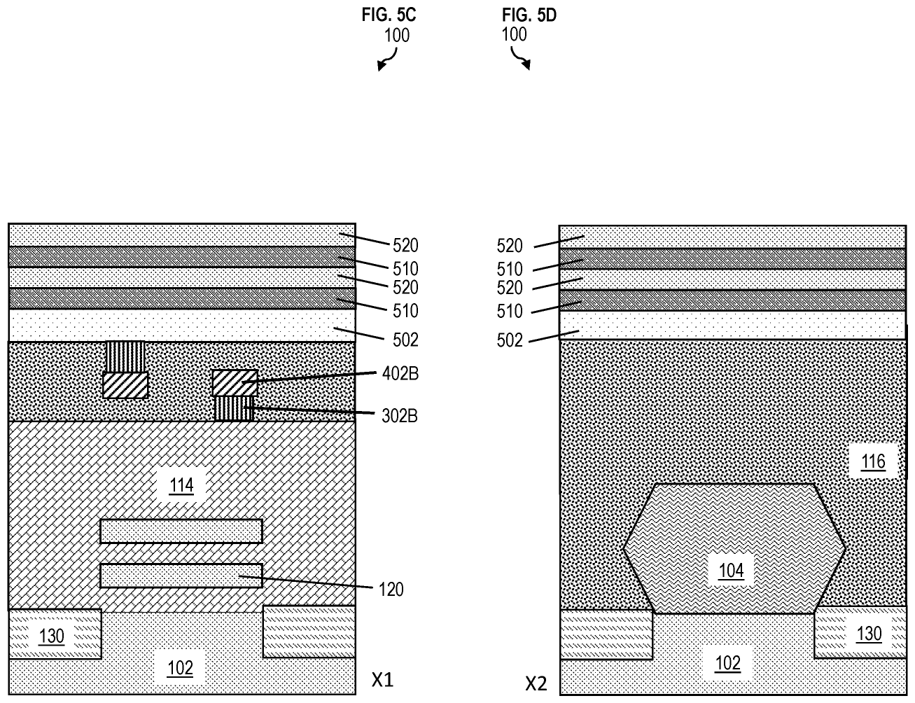

FIGS. 5A, 5B, 5C, and 5D depict the IC 100 after deposition of bonding material and nanosheets. A bonding layer 502 is deposited on top. The bonding layer 502 can be a dielectric material such as silicon dioxide or other suitable materials. Semiconductor layers 510 and 520 are alternately formed on the bonding layer 502. The semiconductor layers 510 are sacrificial layers and can be formed of silicon germanium. The semiconductor layers 520 are to become the top channel regions. Example materials of the semiconductor layers 520 can include silicon. The semiconductor layers 520 may be doped to enhance carrier properties.

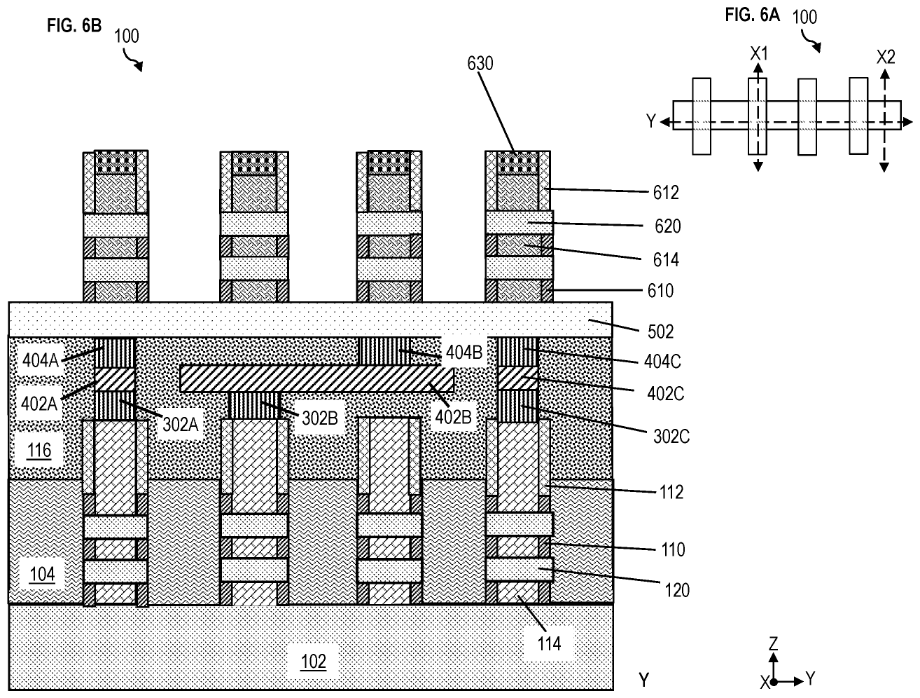

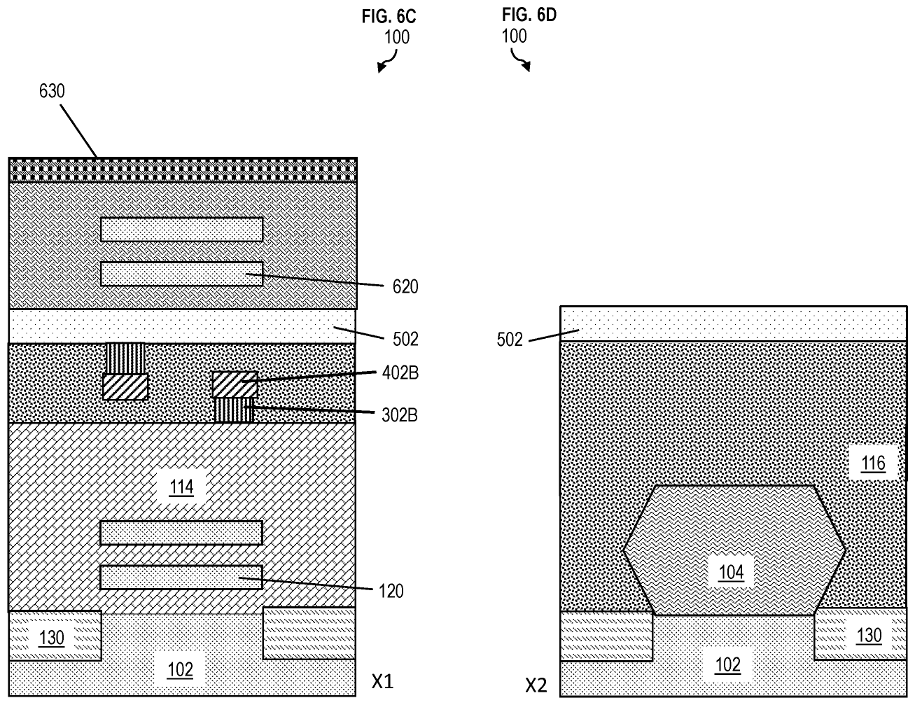

FIGS. 6A, 6B, 6C, and 6D depict the IC 100 after several standard fabrication processes to form top dummy gates and spacers. For example, a fin cut is performed resulting in top channel regions 620. Sides of the semiconductor layers 510 are etched, and dielectric material is deposited to form top inner spacers 610.

A lithography process is performed to form top gate spacers 612, to remove the remaining semiconductor layers 510, and to deposit sacrificial material that forms dummy gates 614. The dummy gates 614 can be formed of amorphous silicon. A gate cap 630 is formed on top of the dummy gates 614. The gate cap 630 can be formed of silicon nitride.

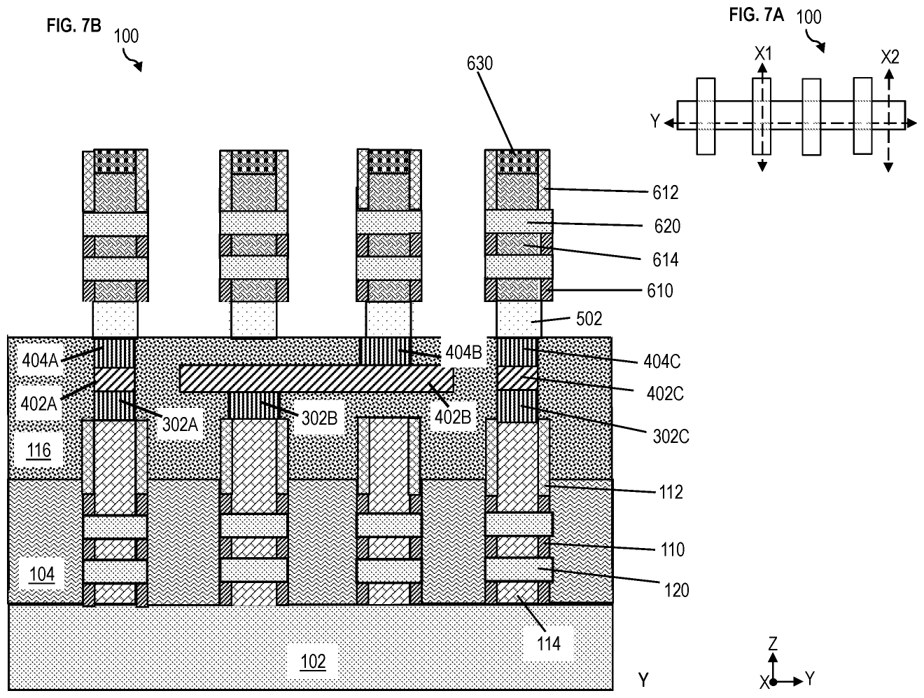

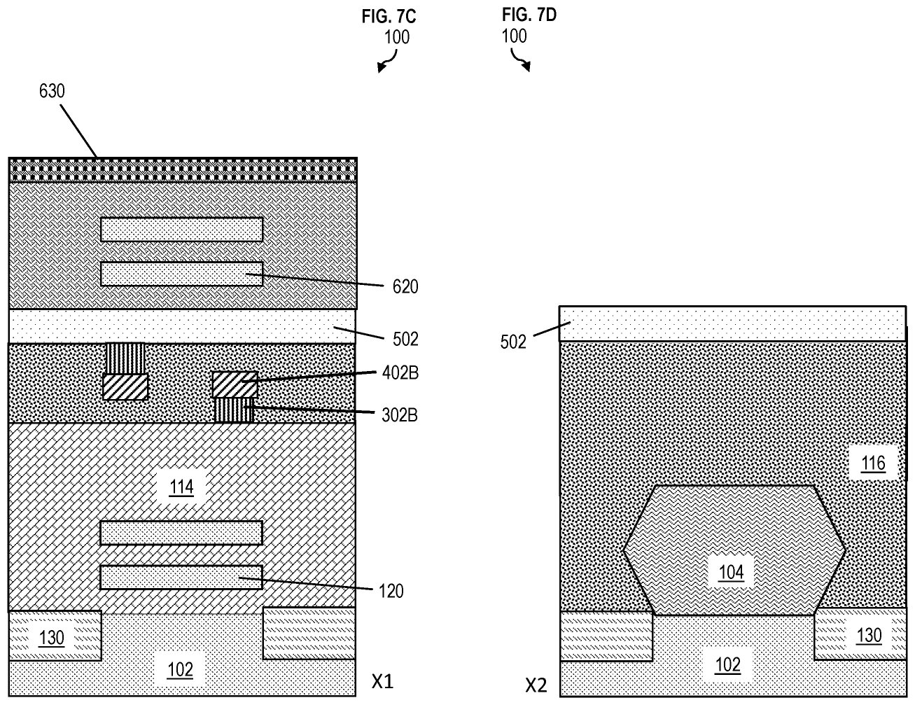

FIGS. 7A, 7B, 7C, and 7D depict the IC 100 after recessing the bonding material. Etching is performed to etch portions of the bonding layer 502. An isotropic etch can be performed.

FIGS. 8A, 8B, 8C, and 8D depict the IC 100 after a directional deposition process. The cross-sectional view of X3 is now depicted in FIG. 8D. A high density plasma chemical vapor deposition (HDPCVD) process can be performed to deposit a middle spacer material 802. The HPDCVD process is directional and only/mainly grows on the horizontal surfaces (and possibly grows slowly on vertical surfaces). Etch back is performed to remove any sidewall material, thereby resulting in the middle spacer material 802. The middle spacer material 802 can be a nitride based dielectric material such as silicon nitride.

FIGS. 9A, 9B, 9C, and 9D depict the IC 100 after growth of epitaxial material. Top source/drain regions 904 are formed adjacent to the top channel regions 602, and an ILD layer 916 is deposited. Etching and/or chemical mechanical planarization/polishing (CMP) can be performed to remove the middle spacer material 802 above the dummy gates 614 in preparation for the replacement metal gate process.

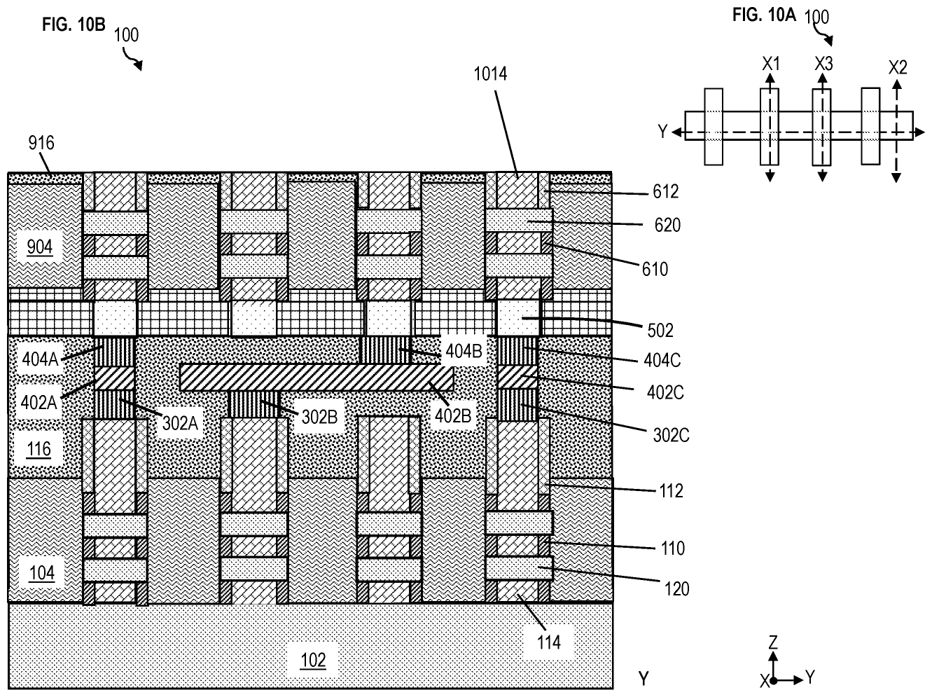

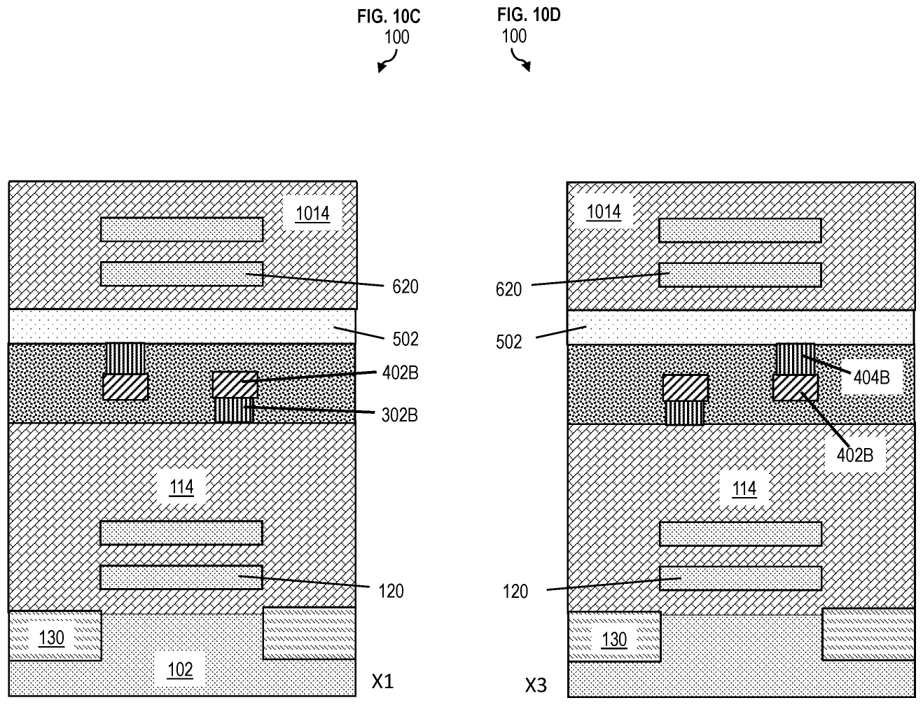

FIGS. 10A, 10B, 10C, and 10D depict the IC 100 after the replacement metal gate process. Etching is performed to expose the dummy gates 614 by removing the gate cap 630. Etching is performed to remove the dummy gates 614, and top gate material 1014 is formed.

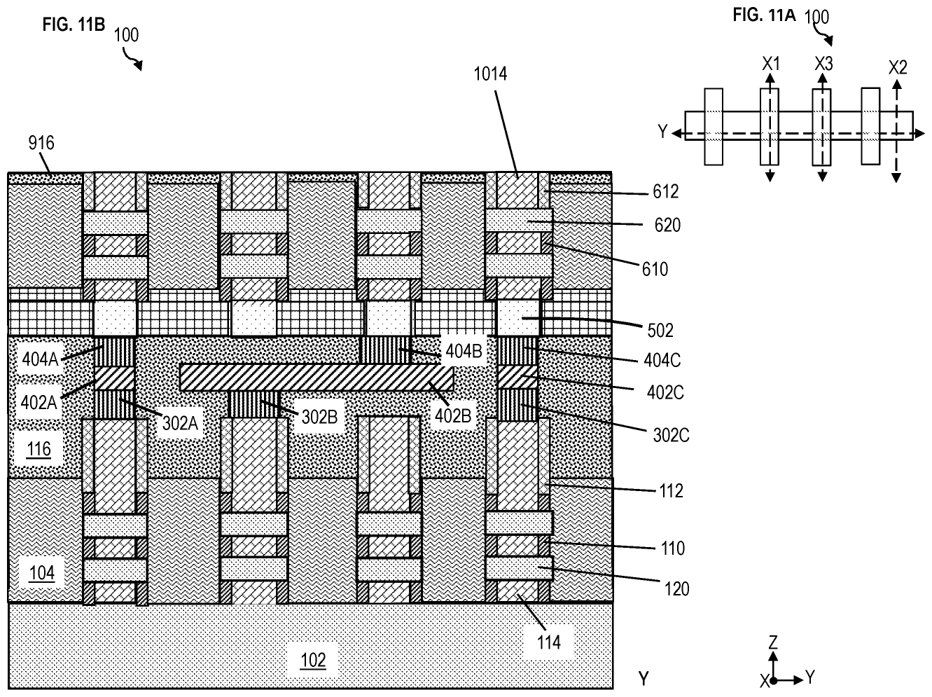

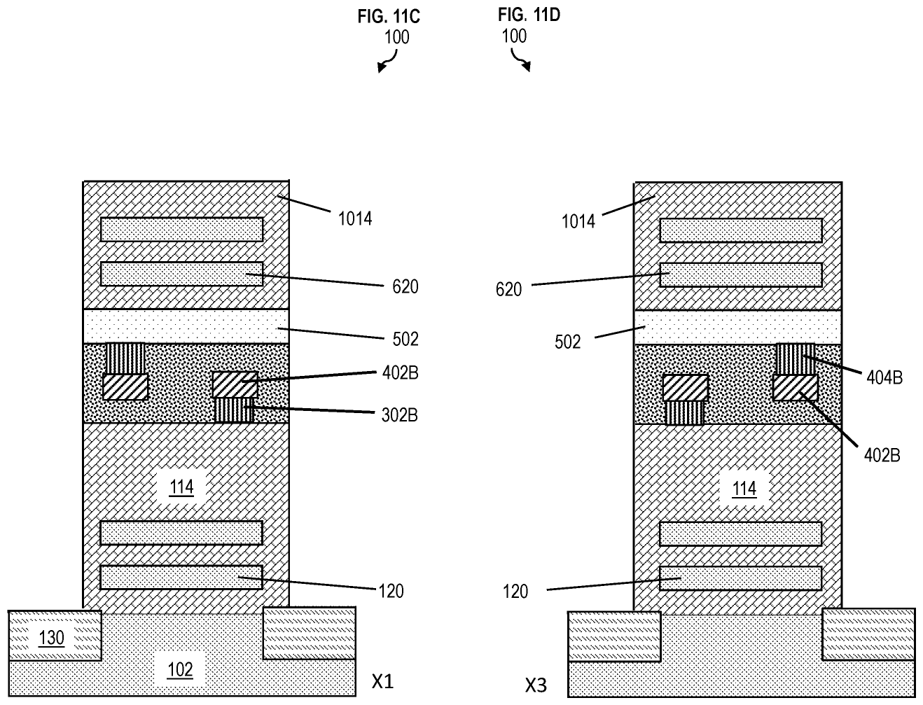

FIGS. 11A, 11B, 11C, and 11D depict the IC 100 after a gate cut. Reactive ion etching is performed to etch portions of the top gate material 1014 and the bottom gate material 114, along with portions of the bonding layer 502 and the ILD layer 116.

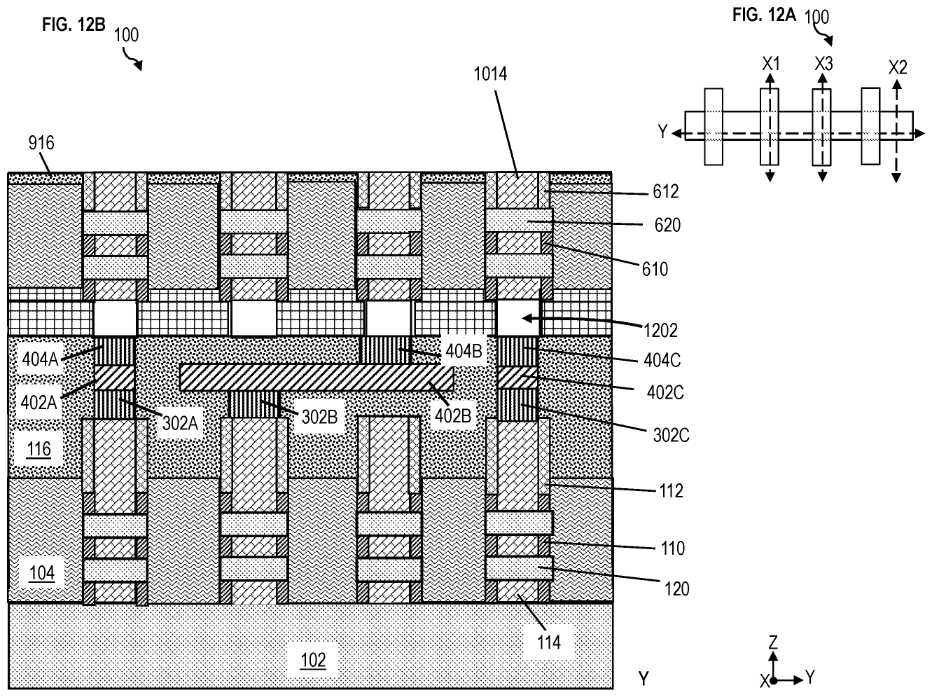

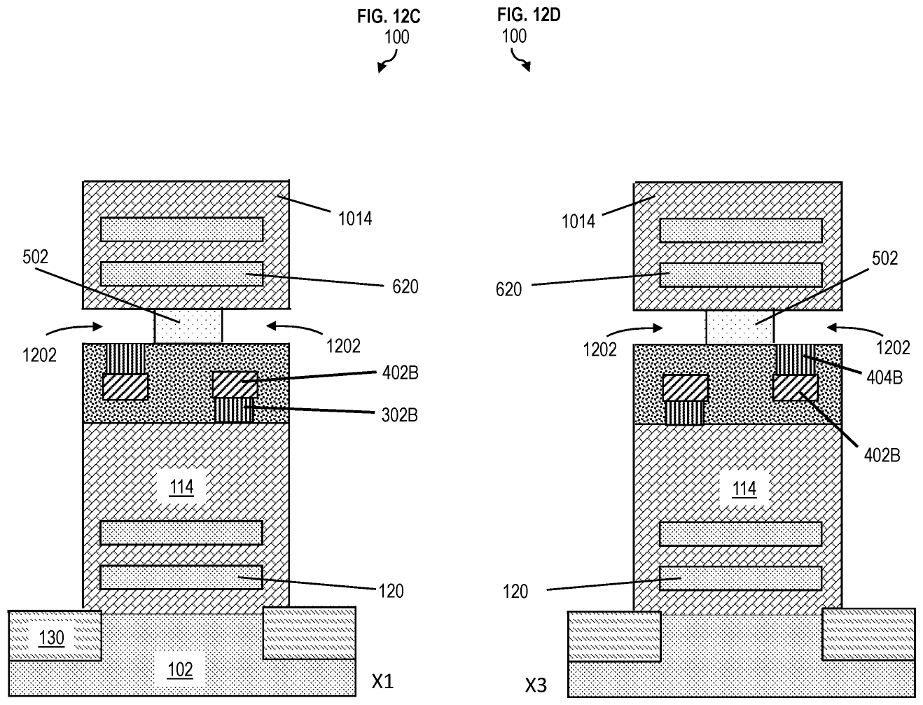

FIGS. 12A, 12B, 12C, and 12D depict the IC 100 after selective recessing of the bonding material. Etching is performed to recess portions of the bonding layer 502, resulting in gaps 1202 in preparation for depositing metal connections. An example etchant may include diluted hydrofluoric acid (HF₂).

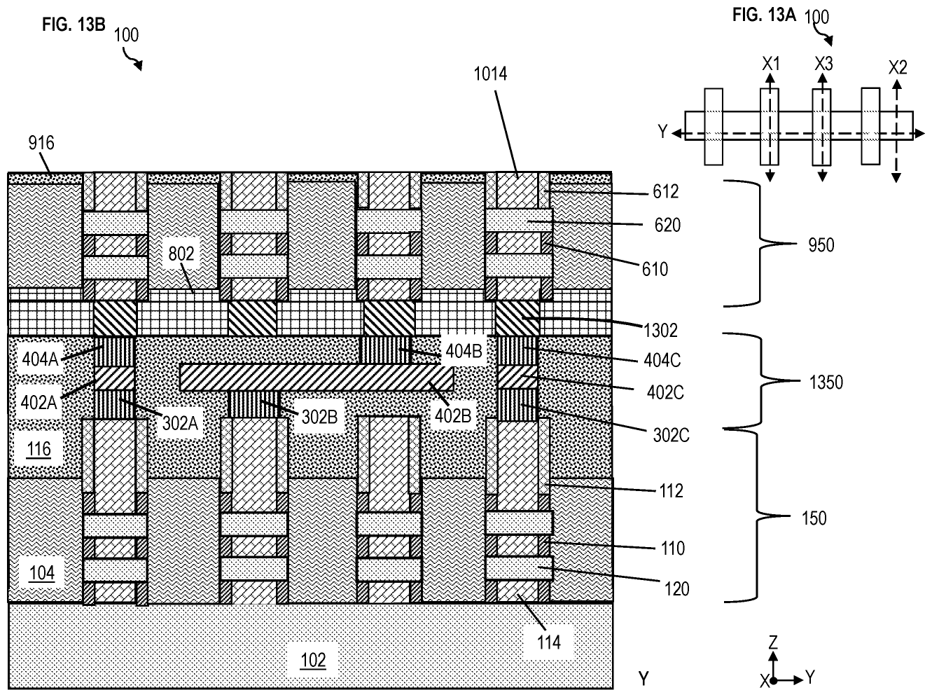

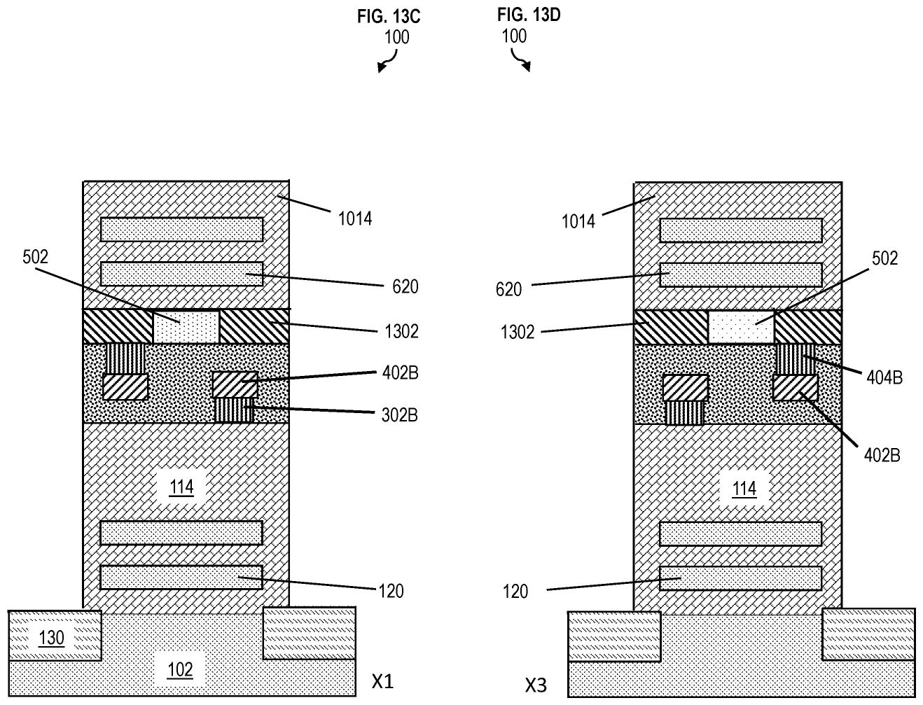

FIGS. 13A, 13B, 13C, and 13D depict the IC 100 after filling the gaps with metal. Metal is deposited to fill in the gaps 1202, thereby forming metal connections 1302. Particularly, the metal is deposited such that the material pinches off in the gaps 1202, and etch back is performed to remove any excess metal. Examples materials of the metal connections may include titanium nitride (TiN), etc.

To illustrate the cross connection or cross couple between a bottom transistor and a top transistor in FIG. 13B, the bottom gate material 114 of one of the bottom transistors 150 is electrically connected to the gate material 1014 of one of the top transistors. For example, the bottom gate material 114 of one of the bottom transistors 150 is connected to the metal via 302B, the metal wire/line 402B is connected to both the metal via 302B below and the metal via 404B above, and the metal via 404B is connected to the gate material 1014 of one of the top transistors 950. In one or more embodiments, the metal via 404B can be connected to the gate material 1014 the top transistors 950 through the metal connection 1302. In one or more embodiments, the metal connections 1302 may not be present, and the gate material 1014 is formed on the metal via 404B to make the connection. In one or more embodiments, the metal vias 302A, 302B, and 302C, the metal wires/lines 402A, 402B, and 402C, and the metal vias 404A, 404B, and 404C all form an interconnect layer 1350 or interconnect structure between the stacked bottom transistors 150 and top transistors 950.

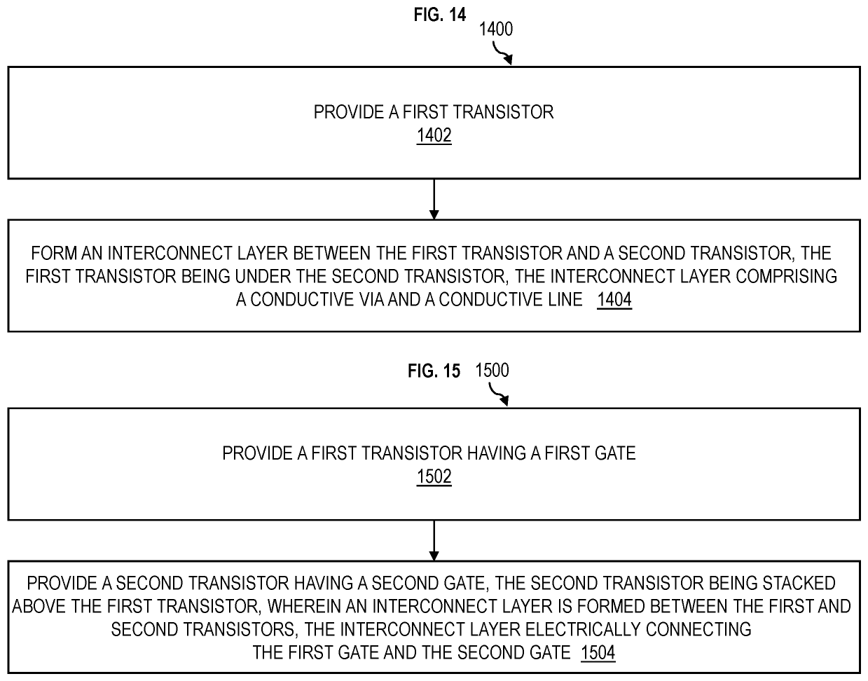

FIG. 14 depicts a flowchart of a method 1400 of forming a semiconductor structure, such as the IC 100, according to one or more embodiments. Reference can be made to any of the figures discussed herein. At block 1402, the method 1400 includes providing a first transistor (e.g., bottom transistors 150). At block 1404, the method 1400 includes forming an interconnect layer 1350 between the first transistor (e.g., bottom transistors 150) and a second transistor (e.g., top transistors 950), the first transistor being under the second transistor, the interconnect layer including a conductive via (e.g., metal vias 302) and a conductive line (e.g., metal wires/lines 402).

Further, the interconnect layer 1350 electrically connects the first transistor to the second transistor. The interconnect layer 1350 electrically connects a first gate (e.g., bottom gate material 114) of the first transistor to a second gate (e.g., top gate material 1014) of the second transistor. The conductive via (e.g., metal vias 302B) connects the first transistor (e.g., bottom transistors 150) to the conductive line (e.g., metal wire/line 402B). Another conductive via (e.g., metal via 404B) connects the second transistor (e.g., top transistors 950) to the conductive line (e.g., metal wire/line 402B). A space between the first transistor and the second transistor includes the conductive via, the conductive line, and the another conductive via (e.g., metal via 302B, metal wire/line 402B, and metal via 404B). A first gate (e.g., bottom gate material 114) of the first transistor is connected to a conductive connection, another conductive via being connected to both the conductive connection and the conductive line, the conductive line being connected to the conductive via; a second gate (e.g., top gate material 1014) of the second transistor is connected to the conductive via. Gates (e.g., bottom gate material 114 and top gate material 1014) of the first and second transistors are connected by the interconnect layer 1350 for simultaneous control.

A first gate of the first transistor (e.g., one of the top transistors 950) is directly under a second gate of the second transistor (e.g., one of the bottom transistors 150); or the first gate of the first transistor (e.g., one of the top transistors 950) is diagonally offset under the second gate of the second transistor (e.g., one of the bottom transistors 150).

Additionally, a top tier (e.g., the location of the top transistors 950) includes the second transistor (e.g., one of the top transistors 950) and a fourth transistor (e.g., another one of the top transistors 950 to the left or right), the fourth transistor being laterally adjacent to the second transistor; a bottom tier (e.g., the location of the bottom transistors 150) includes the first transistor (e.g., one of the bottom transistors 150) and a third transistor (e.g., another one of the bottom transistors 150), the first transistor being directly below the second transistor, the third transistor being directly below the fourth transistor; gates (e.g., one of the bottom gate materials 114 and one of the top gate materials 1014) of the first and fourth transistors are connected and other gates (e.g., another one of the bottom gate materials 114 and another one of the top gate materials 1014) of the second and third transistors are connected. As such, this has two separate metal wires/lines (only one is illustrated in FIG. 13B) that are elongated in the y-axis like the metal wire/line 402B in order to form cross connections of the gates of the four transistors discussed above.

FIG. 15 depicts a flowchart of a method 1500 of forming a semiconductor structure, such as the IC 100, according to one or more embodiments. Reference can be made to any of the figures discussed herein. At block 1502, the method 1500 includes providing a first transistor having a first gate (e.g., bottom transistors 150 having bottom gate material 114). At block 1504, the method 1500 includes providing a second transistor having a second gate (e.g., top transistors 950 having top gate material 1014), the second transistor being stacked above the first transistor, where an interconnect layer 1350 is formed between the first and second transistors, the interconnect layer 1350 electrically connecting the first gate and the second gate.

Further, the interconnect layer 1350 include a first conductive via, a conductive line, and a second conductive via. The interconnect layer 1350 includes a first conductive via that connects to the first gate, a second conductive via that connects to the second gate, and a conductive line connected to both the first and second conductive vias.

A conductive connection (e.g., metal connections 1302) connects the first gate to a first conductive via; the interconnect layer 1350 include the first conductive via connected to the conductive connection (e.g., metal connections 1302), a second conductive via connected to the second gate, and a conductive line connected to both the first and second conductive vias.

Gate material formed around the fins or nanosheets includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

In one or more embodiments, the ILD material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present disclosure for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a first transistor stacked under a second transistor; and
an interconnect layer between the first and second transistors, the interconnect layer comprising a conductive via and a conductive line.

2. The semiconductor structure of claim 1, wherein the interconnect layer electrically connects the first transistor to the second transistor.

3. The semiconductor structure of claim 1, wherein the interconnect layer electrically connects a first gate of the first transistor to a second gate of the second transistor.

4. The semiconductor structure of claim 1, wherein the conductive via connects the first transistor to the conductive line.

5. The semiconductor structure of claim 4, wherein another conductive via connects the second transistor to the conductive line.

6. The semiconductor structure of claim 5, wherein a space between the first transistor and the second transistor comprises the conductive via, the conductive line, and the another conductive via.

7. The semiconductor structure of claim 1, wherein:
a first gate of the first transistor is connected to a conductive connection, another conductive via being connected to both the conductive connection and the conductive line, the conductive line being connected to the conductive via; and
a second gate of the second transistor is connected to the conductive via.

8. The semiconductor structure of claim 1, wherein a first gate of the first transistor and a second gate of the second transistor are connected by the interconnect layer for simultaneous control.

9. The semiconductor structure of claim 1, wherein:
a first gate of the first transistor is directly under a second gate of the second transistor; or
the first gate of the first transistor is diagonally offset under the second gate of the second transistor.

10. The semiconductor structure of claim 1, wherein:
a top tier comprises the second transistor and a fourth transistor, the fourth transistor being laterally adjacent to the second transistor;
a bottom tier comprises the first transistor and a third transistor, the first transistor being directly below the second transistor, the third transistor being directly below the fourth transistor; and
gates of the first and fourth transistors are connected and other gates of the second and third transistors are connected.

11. A method comprising:
providing a first transistor; and
forming an interconnect layer between the first transistor and a second transistor, the first transistor being under the second transistor, the interconnect layer comprising a conductive via and a conductive line.

12. The method of claim 11, wherein the interconnect layer electrically connects the first transistor to the second transistor.

13. The method of claim 11, wherein the interconnect layer electrically connects a first gate of the first transistor to a second gate of the second transistor.

14. The method of claim 11, wherein the conductive via connects the first transistor to the conductive line.

15. The method of claim 14, wherein another conductive via connects the second transistor to the conductive line.

16. The method of claim 15, wherein a space between the first transistor and the second transistor comprises the conductive via, the conductive line, and the another conductive via.

17. The method of claim 11, wherein:
a first gate of the first transistor is connected to a conductive connection, another conductive via being connected to both the conductive connection and the conductive line, the conductive line being connected to the conductive via; and
a second gate of the second transistor is connected to the conductive via.

18. The method of claim 11, wherein a first gate of the first transistor and a second gate of the second transistor are connected by the interconnect layer for simultaneous control.

19. A semiconductor structure comprising:
a first transistor having a first gate;
a second transistor having a second gate, the second transistor being stacked above the first transistor; and
an interconnect layer formed between the first and second transistors, the interconnect layer electrically connecting the first gate and the second gate.

20. The semiconductor structure of claim 19, wherein the interconnect layer comprises a first conductive via, a conductive line, and a second conductive via.

21. The semiconductor structure of claim 19, wherein the interconnect layer comprises a first conductive via that connects to the first gate, a second conductive via that connects to the second gate, and a conductive line connected to both the first and second conductive vias.

22. The semiconductor structure of claim 19, wherein:
a conductive connection connects the first gate to a first conductive via; and
the interconnect layer comprises the first conductive via connected to the conductive connection, a second conductive via connected to the second gate, and a conductive line connected to both the first and second conductive vias.

23. The semiconductor structure of claim 19, wherein the first and second gates are connected by the interconnect layer for simultaneous control.

24. A method comprising:
providing a first transistor having a first gate; and
providing a second transistor having a second gate, the second transistor being stacked above the first transistor, wherein an interconnect layer is formed between the first and second transistors, the interconnect layer electrically connecting the first gate and the second gate.

25. The method of claim 24, wherein the interconnect layer comprises a first conductive via, a conductive line, and a second conductive via.
